(19) United States
(12) Patent Application Publication
(10) Pub. No.: US 2026/0305805 A1
(43) Pub. Date: Oct. 8, 2026

(54) BACK CLIP FOR ELECTRONIC DEVICE AND ELECTRONIC DEVICE ASSEMBLY

(71) Applicant: Shanghai Sunmi Technology Co., Ltd., SHANGHAI (CN)

(72) Inventors: Zhican CHEN, Shanghai (CN); Zhe LIN, Shanghai (CN); Laibing GU, Shanghai (CN)

(73) Assignee: Shanghai Sunmi Technology Co., Ltd., SHANGHAI (CN)

(21) Appl. No.: 19/630,479

(22) Filed: Mar. 27, 2026

(30) Foreign Application Priority Data
Apr. 8, 2025 (CN) 202520651729.9

(51) Int. Cl. A45F 5/00

(52) U.S. Cl. CPC A45F 5/1516; A45F 5/1525; A45F 2005/008

(57) ABSTRACT

A back clip for electronic devices includes a first shell, a second shell, and a locking fastener; the second shell is movably disposed on the first shell along a first direction, and includes a main body and a first limiting portion provided on the main body; the locking fastener being movable along a second direction to a first position and a second position of the first shell, the second direction being perpendicular to the first direction; when the locking fastener is located at the first position, the locking fastener engages with the first limiting portion, and the main body cooperates with the first shell to secure the electronic device; when the locking fastener is located at the second position, the locking fastener is disengaged from the first limiting portion, and the main body is movable away from the first shell along the first direction to release the electronic device.

### CROSS REFERENCE TO RELATED APPLICATIONS

This application claims the priority benefit of China application serial no. 202520651729.9, filed on April 8, 2025. The entirety of the above-mentioned patent application is hereby incorporated by reference herein and made a part of this specification.

### TECHNICAL FIELD

This disclosure relates to the technical field of electronic equipment accessories, and particularly refers to a back clip for an electronic device and an electronic device assembly.

### BACKGROUND

With the widespread use of electronic devices such as mobile phones and tablet computers, back clips as an auxiliary accessory have gradually gained attention. The primary function of a back clip is to secure an electronic device through a buckle mechanism, allowing users to either fasten the device to their wrist or place it on a flat surface. This design helps free the user's hands and prevents hand fatigue caused by prolonged holding of the device.

Currently, most back clips for electronic devices utilize screw-fixed buckles to securely lock the electronic device in place. However, when securing or removing the electronic device, users must rely on auxiliary tools such as screwdrivers to disassemble the buckle, which is cumbersome and reduces the convenience of use.

### SUMMARY

The purpose of this disclosure is to provide a back clip for electronic devices and an electronic device assembly. By moving the locking fastener, the electronic device can be secured or released, the operation of which is simple thereby improving the ease of use.

The technical solution provided in this disclosure is as follows:

On one hand, a back clip for electronic devices is provided, comprising:
a first shell;
a second shell, movably disposed on the first shell along a first direction, the second shell comprises a main body and a first limiting portion provided on the main body; and
a locking fastener, disposed on the first shell, and the locking fastener being movable along a second direction to a first position and a second position of the first shell, the second direction being perpendicular to the first direction;
when the locking fastener is located at the first position, the locking fastener engages with the first limiting portion, and the main body cooperates with the first shell to secure the electronic device;
when the locking fastener is located at the second position, the locking fastener is disengaged from the first limiting portion, and the main body is movable away from the first shell along the first direction to release the electronic device.

In some embodiments, the locking fastener comprises a first inclined surface on a side facing the main body in the first direction, and the main body comprises a second inclined surface configured to engage with the first inclined surface;when the locking fastener moves from the first position to the second position, the first inclined surface engages with the second inclined surface to drive the main body to move away from the first shell along the first direction.

In some embodiments, the locking fastener comprises a third inclined surface on a side away from the main body in the first direction, and the first limiting portion comprises a fourth inclined surface; when the locking fastener moves from the second position to the first position, the third inclined surface engages with the fourth inclined surface to drive the main body to move toward the first shell along the first direction.

In some embodiments, the second shell further comprises a second limiting portion, the second limiting portion is disposed on the main body, and when the locking fastener is located at the second position, the locking fastener engages with the second limiting portion to restrict the main body from detaching from the first shell.

In some embodiments, along the first direction, a vertical distance from a side of the second limiting portion adjacent to the main body to a top surface of the main body is greater than a vertical distance from a side of the first limiting portion adjacent to the main body to the top surface of the main body.

In some embodiments, the first shell is provided with a limiting groove, and the locking fastener is provided with a limiting protrusion; wherein when the locking fastener is located at the first position, the limiting protrusion is located within the limiting groove to secure the locking fastener.

In some embodiments, the number of the first limiting portion and the locking fastener are both two, the two first limiting portions are arranged at intervals along the second direction, and the two locking fasteners are arranged in one-to-one correspondence with the two first limiting portions.

In some embodiments, the first limiting portion comprises a first connecting part and a first engaging part, the first connecting part extends along the first direction, and the first engaging part extends along the second direction; when the locking fastener is located at the first position, the first engaging part is engaged with the locking fastener; a guide slot is formed between the two first connecting parts; a guide portion is provided on an inner side of the first shell, the guide portion being disposed in the guide slot and movable along the first direction within the guide slot.

In some embodiments, a first flange extending along the first direction is provided on a side of the first connecting part adjacent to the guide portion, a second flange extending along the first direction is provided on the guide portion; the first flange is located between the second flange and the first shell to restrict movement of the first limiting portion.

On the other hand, an electronic device assembly is also provided, comprising an electronic device and the back clip of the electronic device according to any of the above embodiments.

The technical effect of the present disclosure lies in that: the movement of the locking fastener enables the electronic device to be secured or released. This configuration not only ensures the device to remain firmly secured but also to make the securing and releasing processes simple and rapid, eliminating the need for auxiliary tools, thereby significantly improving the convenience of use.

### BRIEF DESCRIPTION OF THE DRAWINGS

The present disclosure will be further elaborated below in conjunction with the accompanying drawings and specific embodiments:

FIG. 1 is a structural schematic diagram of a back clip for an electronic device provided in the embodiment of the present disclosure, with the locking fastener located at the second position;

FIG. 2 is a schematic structural diagram of a back clip for electronic devices provided in the embodiment of the present disclosure, with the locking fastener located at the first position;

FIG. 3 is a structural schematic diagram of a first shell provided in the embodiment of the present disclosure;

FIG. 4 is a structural schematic diagram of a locking fastener provided in the embodiment of the present disclosure;

FIG. 5 is a structural schematic diagram of the second shell provided in the embodiment of the present disclosure;

FIG. 6 is an exploded schematic diagram of a back clip for an electronic device provided in the embodiment of the present disclosure.

Explanation of attached drawing numbers:

100. First shell; 110. Limiting groove; 120. Guide portion; 121. Second flange; 130. First sliding slot; 140. Second sliding slot;

200. Second shell; 210. Main body; 211. Second inclined surface; 220. First limiting portion; 221. Fourth inclined surface; 222. First connecting part; 2221. First flange; 223. First engaging part; 230. Second limiting portion; 231. Second connecting part; 232. Second engaging part; 240. Guide slot;

300. Locking fastener; 310. Limiting protrusion; 320. Locking body; 321. First inclined surface; 322. Third inclined surface; 330. Operating part;

400. Cavity;

500. Buckle.

### PREFERRED EMBODIMENT OF THE PRESENT DISCLOSURE

In the following description, specific details such as specific system structures and technologies are set forth for illustrative rather than restrictive purposes, so as to provide a thorough understanding of the embodiments of the present disclosure. However, it will be apparent to those skilled in the art that the present disclosure may also be implemented in other embodiments without these specific details. In other instances, detailed descriptions of well-known systems, devices, circuits, and methods are omitted so as not to obscure the description of the present disclosure with unnecessary details.

To more clearly illustrate the technical solutions in the embodiments of the present disclosure or the prior art, the specific implementations of the present disclosure will be described below with reference to the accompanying drawings. Obviously, the accompanying drawings in the following description are only some embodiments of the present disclosure, and for those of ordinary skill in the art, other accompanying drawings and other implementations can be obtained based on these drawings without exerting creative effort.

To keep the drawings concise, only the parts relevant to the present disclosure are schematically shown in each figure, and they do not represent the actual structure of the product. In addition, to make the drawings concise and easy to understand, for parts with the same structure or function in some figures, only one of them is schematically illustrated or labeled. As used herein, the term "one" not only means "exactly one" but also may refer to a situation of "more than one".

It should be further understood that the term "and/or" used in the specification of the present disclosure and the appended claims refers to any and all possible combinations of one or more of the associated listed items, and includes such combinations.

As used herein, it should be noted that unless otherwise explicitly specified and limited, the terms "installation", "connection" and "linkage" shall be understood in a broad sense. For example, it may refer to a fixed connection, a detachable connection, or an integral connection; it may be a mechanical connection or an electrical connection; it may be a direct connection, an indirect connection through an intermediate medium, or internal communication between two components. For those of ordinary skill in the art, the specific meanings of the above terms in the present disclosure can be understood according to specific circumstances.

In the embodiments shown in the accompanying drawings, the indications of directions (such as up, down, left, right, front, and rear, etc.) are not absolute but relative when describing the structure and movement of each component, and are not intended to limit the direction of the product during actual use.

In addition, in the description of the present disclosure, ordinal numbers such as "first" and "second" are only used to distinguish and describe associated objects, and shall not be construed as indicating or implying the relative importance or order of the associated objects.

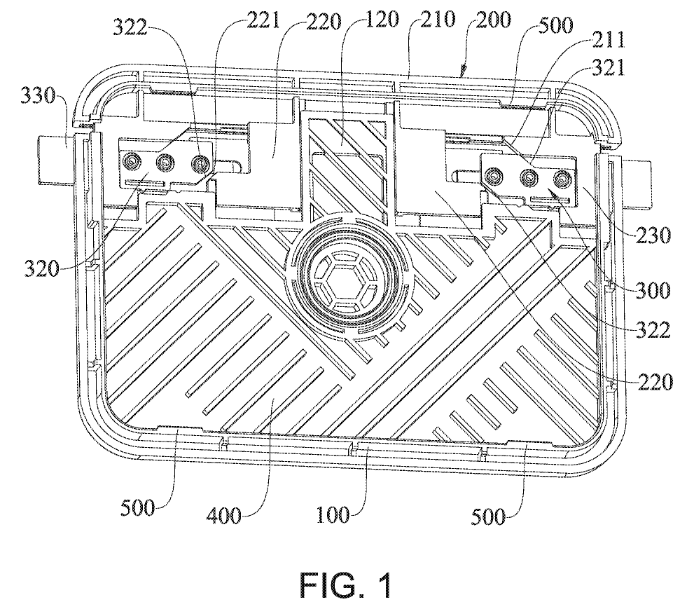

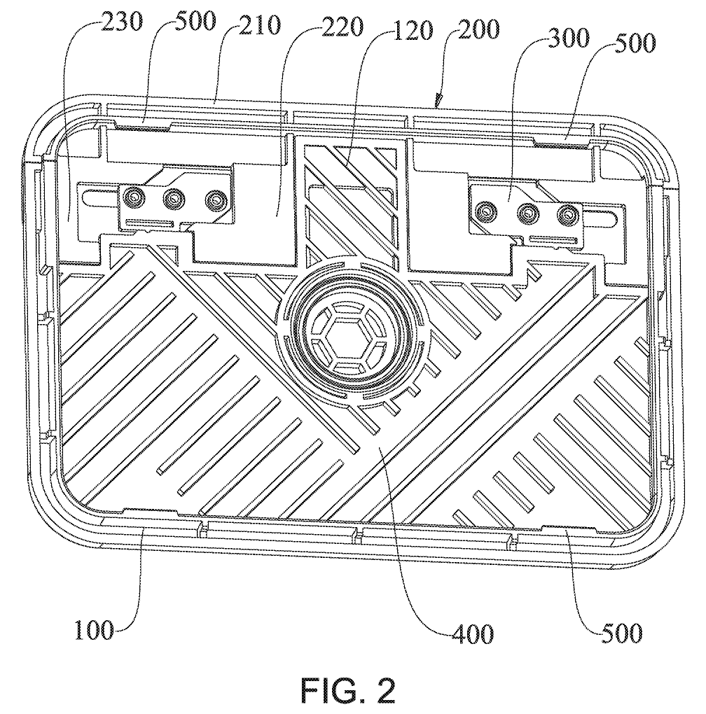

As shown in FIGS. 1 and 2, in one or more embodiments, the present disclosure provides a back clip for an electronic device, comprising a first shell 100, a second shell 200, and a locking fastener 300; the second shell 200 is movably disposed on the first shell 100 along a first direction, and the second shell 200 comprises a main body 210 and a first limiting portion 220 provided on the main body 210; the locking fastener 300 is disposed on the first shell 100, and the locking fastener 300 is movable along a second direction to a first position and a second position of the first shell 100, with the second direction being perpendicular to the first direction; when the locking fastener 300 is located at the first position, the locking fastener 300 engages with the first limiting portion 220, and the main body 210 cooperates with the first shell 100 to secure the electronic device; when the locking fastener 300 is located at the second position, the locking fastener 300 is disengaged from the first limiting portion 220, and the main body 210 can move away from the first shell 100 along the first direction to release the electronic device.

Specifically, the first shell 100 serves as the base component of the back clip, configured to mount and support the second shell 200 and the locking fastener 300. The second shell 200 is movably disposed on the first shell 100 along a first direction, which may be the length direction or the width direction of the first shell 100. When the second shell 200 moves into position toward the first shell 100 along the first direction, the main body 210 of the second shell 200 and the first shell 100 can enclose to form a cavity 400 with an opening. The electronic device can be directly mounted in the cavity 400, where the electronic device is in an interference fit with the cavity 400 to secure the electronic device; alternatively, the electronic device is provided with a boss structure, and the boss structure on the electronic device is mounted in the cavity 400, and the boss structure on the electronic device is in an interference fit with the cavity 400 to secure the electronic device. When the second shell 200 moves away from the first shell 100 along the first direction, the size of the cavity 400 increases, and the electronic device can be removed from the cavity 400 to achieve detachment of the electronic device from the back clip. Preferably, the first shell 100 and the main body 210 of the second shell 200 may each be provided with a buckle 500. When the electronic device is mounted in the cavity 400 formed by the first shell 100 and the second shell 200, the buckle 500 further limits the position of the electronic device to enhance the stability of the electronic device on the back clip.

The locking fastener 300 is movably disposed on the first shell 100 along a second direction, and the second direction is perpendicular to the first direction. Specifically, when the first direction is the length direction of the first shell 100, the second direction is the width direction of the first shell 100; when the first direction is the width direction of the first shell 100, the second direction is the length direction of the first shell 100.

The locking fastener 300 moves between a first position and a second position on the first shell 100. When the locking fastener 300 moves to the first position, it engages with the first limiting portion 220 of the second shell 200 to fix the position of the second shell 200, enabling the second shell 200 and the first shell 100 to enclose and form the cavity 400 for securing the electronic device. When the locking fastener 300 moves to the second position, it disengages from the first limiting portion 220 of the second shell 200, allowing the second shell 200 to move away from the first shell 100 to release the electronic device, so that the electronic device can be removed from the back clip. In this embodiment, the movement of the locking fastener 300 enables the securing or unlocking of the electronic device. This design not only achieves firm fixation but also features simple operation. It eliminates the need for external tools, thereby improving the convenience of use.

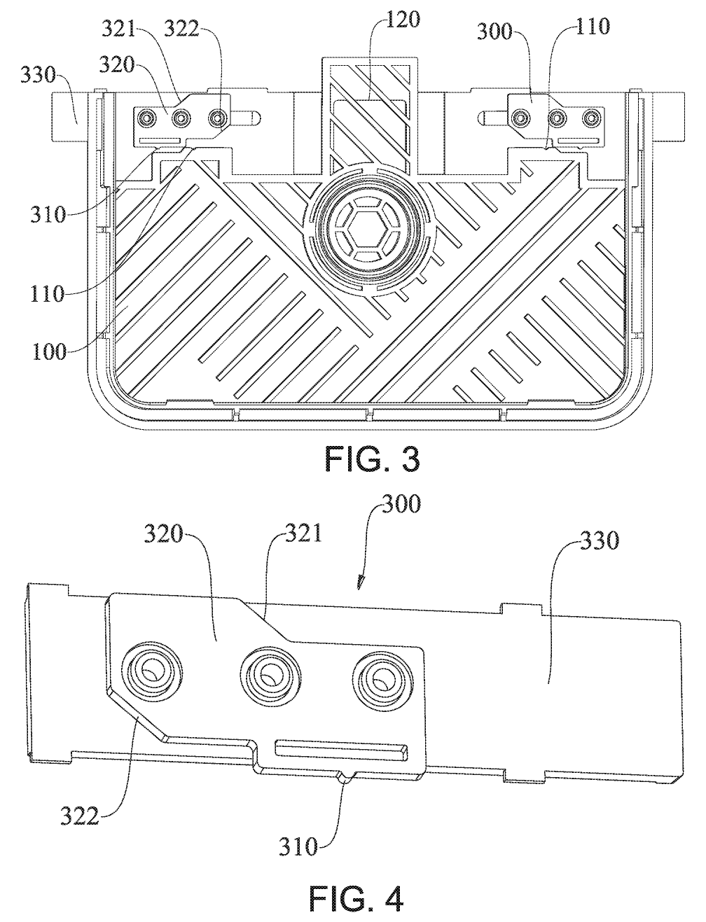

Furthermore, in one embodiment, the back clip further comprises an elastic member, which can be a spring. The elastic member is disposed on the first shell 100, with one end connected to the first shell 100 and the other end connected to the locking fastener 300. When the locking fastener 300 is moved to the second position, the spring is in a compressed state. When the locking fastener 300 is released, the elastic member resets, moving the locking fastener 300 to the first position. Under the elastic force of the elastic member, the locking fastener 300 is held in the first position, ensuring that it remains engaged with the first limiting portion 220 of the second shell 200, restricting the movement of the second shell 200, thereby securing the electronic device. As shown in FIG. 3, in an alternative embodiment, the first shell 100 is provided with a limiting groove 110 or a limiting protrusion, and the locking fastener 300 is provided with a limiting protrusion 310 or a limiting groove. When the locking fastener 300 is in the first position, the limiting protrusion 310 is located in the limiting groove 110, fixing the locking fastener 300 in the first position. This ensures that the locking fastener 300 remains engaged with the first limiting portion 220 of the second shell 200, and restricts the movement of the second shell 200, thus securing the electronic device. It should be noted that the locking fastener 300 may also be fixed in the first position by other means, such as bolts, buckles, or the like.

Optionally, as shown in FIG. 4, to facilitate the operation of the locking fastener 300, the locking fastener 300 comprises a locking body 320 and an operating portion 330. The locking body 320 is slidably connected to the first shell 100, and the operating portion 330 is provided at one end of the locking body 320 for the user to operate to move the locking fastener 300. The first shell 100 is further provided with a sliding slot extending along the second direction. The locking body 320 is disposed in the sliding slot and slides along the sliding slot, and the sliding slot can limit the sliding direction of the locking fastener 300, thereby reducing the operation difficulty.

In use, the user moves the locking fastener 300 to the second position by operating the operating portion 330, whereupon the first limiting portion 220 is disengaged from the locking fastener 300, allowing the electronic device to be placed between the first shell 100 and the second shell 200. Then, the user moves the locking fastener 300 to the first position and secures it there via the cooperation of the limiting protrusion 310 and the limiting groove 110; alternatively, the user releases the locking fastener 300, which moves to the first position under the elastic force of the elastic member. At this point, the locking fastener 300 cooperates with the first limiting portion 220 to secure the electronic device within the cavity 400 formed by the first shell 100 and the second shell 200. When the electronic device needs to be released, the user operates the operating portion 330 again to move the locking fastener 300 to the second position, enabling the electronic device to be removed from the cavity 400 formed by the first shell 100 and the second shell 200.

In some embodiments, as shown in FIGS. 1, 4, and 5, a first inclined surface 321 is provided on the side of the locking fastener 300 that is close to the main body 210 along the first direction, and the first inclined surface 321 is disposed on the locking body 320. The main body 210 is provided with a second inclined surface 211 that mates with the first inclined surface 321. When the locking fastener 300 moves from the first position to the second position, the cooperation between the first inclined surface 321 and the second inclined surface 211 causes the main body 210 to move away from the first shell 100 along the first direction.

When the user needs to release the electronic device, all they need to do is move the locking fastener 300 from the first position to the second position. During the movement of the locking fastener 300, the first inclined surface 321 and the second inclined surface 211 gradually come into contact and press against each other. Due to the inclination angle and surface characteristics between the first inclined surface 321 and the second inclined surface 211, the entire second shell 200 receives a gradually increasing pushing force in the first direction. This causes the second shell 200 to move away from the first shell 100 along the first direction. Meanwhile, the distance between the second shell 200 and the first shell 100 increases, and the size of the cavity 400 formed by the second shell 200 and the first shell 100 also increases, allowing the electronic device to be easily removed from the cavity 400. In this embodiment, the entire process of releasing the electronic device requires no additional mechanical components or complex operations. This not only improves the operational convenience when releasing the electronic device but also ensures that the electronic device is released safely and quickly, further enhancing the user experience.

In other embodiments, the first shell 100 may further be provided with an elastic member. The elastic member is disposed between the first shell 100 and the second shell 200, and is configured to push the second shell 200 to move away from the first shell 100 along the first direction when the locking fastener 300 is disengaged from the first limiting portion 220. The elastic member may be a spring, with one end connected to the first shell 100 and the other end connected to the second shell 200.

In some embodiments, as shown in FIGS. 1, 4, and 5, a third inclined surface 322 is provided on the side of the locking fastener 300 away from the main body 210 along the first direction. The third inclined surface 322 is disposed on the locking body 320, and a fourth inclined surface 221 is provided on the first limiting portion 220. When the locking fastener 300 moves from the second position to the first position, the cooperation between the third inclined surface 322 and the fourth inclined surface 221 causes the main body 210 to move toward the first shell 100 along the first direction.

When the user needs to secure the electronic device, all they need to do is to move the locking fastener 300 from the second position to the first position. As the locking fastener 300 moves, the third inclined surface 322 and the fourth inclined surface 221 gradually come into contact and press against each other. Due to their inclination angle and surface characteristics, the main body 210 of the second shell 200 is subjected to a gradually increasing pressure in the first direction. This causes the main body 210 of the second shell 200 to smoothly approach the first shell 100 and, in cooperation with the first shell 100, and envelop the electronic device, thereby securing the electronic device. The entire process requires no additional mechanical components or complex operations, being simple and efficient. It also ensures that the electronic device is secured safely and quickly.

In some embodiments, as shown in FIGS. 1, 2, and 5, the second shell 200 further comprises a second limiting portion 230. The second limiting portion 230 is disposed on the main body 210. When the locking fastener 300 is located at the second position, the locking fastener 300 cooperates with the second limiting portion 230 to restrict the main body 210 from detaching from the first shell 100.

When the locking fastener 300 is located at the second position, the second shell 200 moves a certain distance away from the first shell 100 along the first direction under the cooperation of the first inclined surface 321 and the second inclined surface 211. After that, the second limiting portion 230 of the second shell 200 comes into contact with a specific part of the locking fastener 300 (such as one end or a side surface) and forms a limiting fit, thereby restricting the main body 210 from continuing to move away from the first shell 100, so as to prevent the second shell 200 from detaching from the first shell 100. This limiting fit in the present embodiment is automatically formed when the locking fastener 300 moves to the second position, without requiring additional operational steps, making it simple and practical.

When it is necessary to detach the second shell 200 from the first shell 100, one only needs to perform certain operations, such as applying a certain force or removing the locking fastener 300, to separate the locking fastener 300 from the second limiting portion 230, thereby releasing the limit and allowing the detachment of the second shell 200.

Further, as shown in FIG. 2, along the first direction, the vertical distance from the side of the second limiting portion 230 adjacent to the main body 210 to the top surface of the main body 210 is greater than the vertical distance from the side of the first limiting portion 220 adjacent to the main body 210 to the top surface of the main body 210.

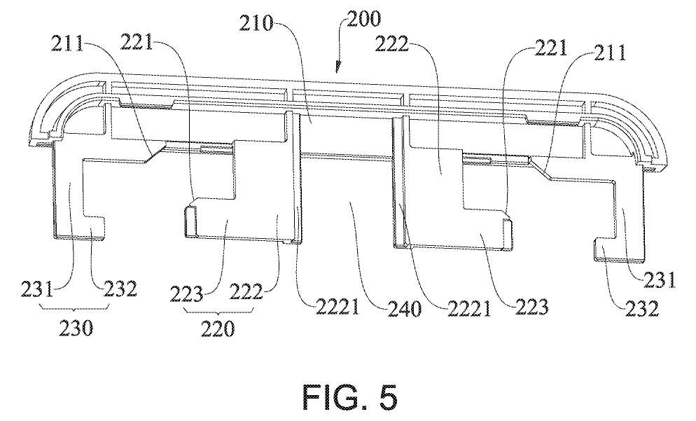

Specifically, as shown in FIG. 5, the first limiting portion 220 comprises a first connecting portion 222 and a first engaging part 223. One end of the first connecting portion 222 is connected to the main body 210, and the other end is connected to the first engaging part 223. The first connecting portion 222 extends along the first direction, and the first engaging part 223 extends along the second direction. The fourth inclined surface 221 is disposed on the first engaging part 223. When the locking fastener 300 is located at the first position, the first engaging part 223 engages with the locking fastener 300 to fix the position of the second shell 200.

The second limiting portion 230 comprises a second connecting portion 231 and a second engaging part 232. One end of the second connecting portion 231 is connected to the main body 210, and the other end is connected to the second engaging part 232. The second connecting portion 231 extends along the first direction, and the second engaging part 232 extends along the second direction. When the locking fastener 300 is located at the second position, the second engaging part 232 engages with the locking fastener 300 to prevent the second shell 200 from detaching from the first shell 100.

The vertical distance from the side of the second engaging part 232 adjacent to the second connecting portion 231 to the top surface of the main body 210 is greater than the vertical distance from the side of the first engaging part 223 adjacent to the first connecting portion 222 to the top surface of the main body 210. When the locking fastener 300 is located at the first position and engaged with the first engaging part 223, there is a certain distance between the second engaging part 232 and the locking fastener 300 along the first direction. This design not only provides sufficient space for the movement of the locking fastener 300 along the second direction, making it more convenient for users to operate the locking fastener 300 without obstruction caused by interference between components, but also ensures that when the locking fastener 300 moves to the second position, the second engaging part 232 will only come into abutment with the locking fastener 300 after the second shell 200 moves a certain distance away from the first shell 100, thereby facilitating the release of the electronic device.

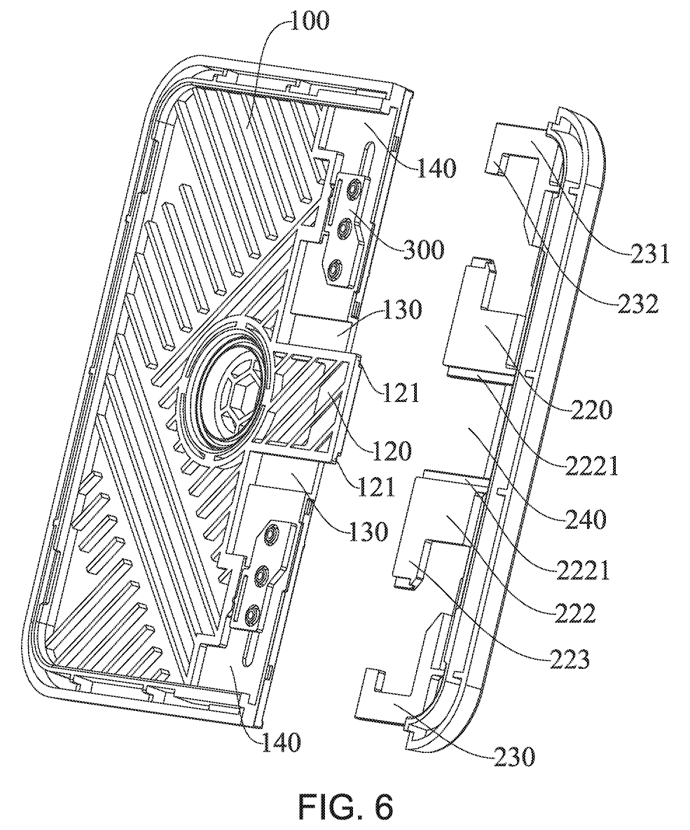

Optionally, as shown in FIG. 6, a first sliding slot 130 and a second sliding slot 140 may further be provided on the inner side of the first shell 100. The first limiting portion 220 is movably disposed in the first sliding slot 130, and the second limiting portion 230 is movably disposed in the second sliding slot 140. The first sliding slot 130 and the second sliding slot 140 can limit the position of the second shell 200.

In some embodiments, as shown in FIG. 2, the number of the first limiting portions 220 and the locking fasteners 300 are both two. The two first limiting portions 220 are arranged at intervals along the second direction, and the two locking fasteners 300 are arranged in one-to-one correspondence with the two first limiting portions 220. The design of the dual limiting portions and dual locking fasteners not only improves the reliability of the back clip when securing the electronic device, but also enhances the symmetry and balance of the back clip, further improving the user experience.

Further, as shown in FIG. 6, a guide slot 240 is formed between the first connecting portions 222 of the two first limiting portions 220; a guide portion 120 is provided on the inner side of the first shell 100, and the guide portion 120 is disposed in the guide slot 240 and is movable in the guide slot 240 along the first direction.

When the user operates the locking fastener 300 to move the second shell 200 toward or away from the first shell 100 along the first direction, the guide portion 120 provided on the inner side of the first shell 100 moves accordingly within the guide slot 240 between the two first limiting portions 220. Due to the restrictive effect of the guide slot 240 on the guide portion 120, the movement trajectory of the second shell 200 is precisely guided, ensuring that the second shell 200 always moves smoothly along the first direction without shaking or shifting caused by external forces or structural gaps, thus making the movement of the second shell 200 smooth and stable. In addition, to reduce friction and wear, the contact surfaces of the guide slot 240 and the guide portion 120 can be made of self-lubricating materials.

Preferably, as shown in FIG. 6, a first flange 2221 extending along the first direction is provided on the side of the first connecting portion 222 adjacent to the guide portion 120, and a second flange 121 extending along the first direction is provided on the guide portion 120. The first flange 2221 is located between the second flange 121 and the first shell 100 to limit the position of the first limiting portion 220.

When the second shell 200 moves along the first direction, the first flange 2221 provided on the first connecting portion 222 cooperates with the second flange 121 on the guide portion 120. Since the first flange 2221 is located between the second flange 121 and the first shell 100, this structure forms a clamping effect, which can firmly restrict the first limiting portion 220 within a certain range and prevent the first limiting portion 220 from tilting or swinging in the direction perpendicular to the plane of the first shell 100. In addition, as the first flange 2221 is positioned between the second flange 121 and the first shell 100, the space between the second flange 121 and the first shell 100 forms a guide channel, thereby achieving the guiding function for the second shell 200 and improving the overall performance and stability of the back clip. In practical applications, the shape and size of the guide channel match those of the first flange 2221 to ensure that the first flange 2221 moves smoothly within the guide channel during the movement of the second shell 200. Meanwhile, the second flange 121 provides sufficient limiting effect on the first flange 2221 to prevent the first limiting portion 220 from tilting.

This embodiment further provides an electronic device assembly, comprising an electronic device and the back clip of the electronic device described in any of the above embodiments. The structure of the back clip is shown in FIGS. 1 to 6. The electronic device can be fixed to the back clip, and the electronic device may be a mobile phone, a tablet computer, an e-reader, or the like. The back clip may be a wristband-type back clip or a stand-type back clip. The wristband-type back clip is provided with a wristband, allowing the user to hold it by hand or fix it on the wrist. The wristband is connected to the back clip through a rotating mechanism to facilitate adjusting the angle of the back clip. The stand-type back clip is provided with a stand for stably placing the back clip on a desktop or other plane. The stand is an angularly adjustable support structure, which can adjust the viewing angle of the electronic device according to the user's needs, meet the user's usage requirements in different scenarios, and improve the practicality and convenience of the back clip.

In the aforementioned embodiments, the description of each embodiment has its own emphasis. For parts not described or recorded in detail in a certain embodiment, reference may be made to the relevant descriptions in other embodiments.

It should be noted that the foregoing embodiments can be freely combined as needed. The above descriptions are merely preferred implementations of the present disclosure. It should be pointed out that for those of ordinary skill in the art, several improvements and modifications can be made without departing from the principles of the present disclosure, and these improvements and modifications should also be regarded as the protection scope of the present disclosure.

What is claimed is:

1. A back clip for an electronic device, comprising:
a first shell;
a second shell, movably disposed on the first shell along a first direction, the second shell including a main body and a first limiting portion provided on the main body; and
a locking fastener, disposed on the first shell, the locking fastener being movable along a second direction to a first position and a second position of the first shell, the second direction being perpendicular to the first direction;
when the locking fastener is located at the first position, the locking fastener engages with the first limiting portion, and the main body cooperates with the first shell to secure the electronic device;
when the locking fastener is located at the second position, the locking fastener is disengaged from the first limiting portion, and the main body is movable away from the first shell along the first direction to release the electronic device.

2. The back clip for an electronic device of claim 1, wherein,
the locking fastener comprises a first inclined surface on a side facing the main body in the first direction, and the main body comprises a second inclined surface configured to engage with the first inclined surface;
when the locking fastener moves from the first position to the second position, the first inclined surface engages with the second inclined surface to drive the main body to move away from the first shell along the first direction.

3. The back clip for an electronic device of claim 2, wherein,
the locking fastener comprises a third inclined surface on a side away from the main body in the first direction, and the first limiting portion comprises a fourth inclined surface;
when the locking fastener moves from the second position to the first position, the third inclined surface engages with the fourth inclined surface to drive the main body to move toward the first shell along the first direction.

4. The back clip for an electronic device of claim 1, wherein,
the second shell further comprises a second limiting portion, the second limiting portion is disposed on the main body, and when the locking fastener is located at the second position, the locking fastener engages with the second limiting portion to restrict the main body from detaching from the first shell.

5. The back clip for an electronic device of claim 4, wherein,
along the first direction, a vertical distance from a side of the second limiting portion adjacent to the main body to a top surface of the main body is greater than a vertical distance from a side of the first limiting portion adjacent to the main body to the top surface of the main body.

6. The back clip for an electronic device of claim 1, wherein,
the first shell is provided with a limiting groove, and the locking fastener is provided with a limiting protrusion, wherein when the locking fastener is located at the first position, the limiting protrusion is located within the limiting groove to secure the locking fastener.

7. The back clip for an electronic device of claim 1, wherein,
number of the first limiting portion and the locking fastener are both two, the two first limiting portions are arranged at intervals along the second direction, and the two locking fasteners are arranged in one-to-one correspondence with the two first limiting portions.

8. The back clip for an electronic device of claim 7, wherein,
the first limiting portion comprises a first connecting part and a first engaging part, the first connecting part extending along the first direction, and the first engaging part extending along the second direction, and when the locking fastener is located at the first position, the first engaging part is engaged with the locking fastener;
a guide slot is formed between two first connecting parts;
a guide portion is provided on an inner side of the first shell, the guide portion being disposed in the guide slot and movable along the first direction within the guide slot.

9. The back clip for an electronic device of claim 8, wherein,
a first flange extending along the first direction is provided on a side of the first connecting part adjacent to the guide portion, a second flange extending along the first direction is provided on the guide portion and the first flange is located between the second flange and the first shell to restrict movement of the first limiting portion.

10. An electronic device assembly, comprising:
an electronic device; and
the back clip for the electronic device of claim 1.
